(19) United States
(12) Patent Application Publication
(10) Pub. No.: US 2026/0221756 A1
(43) Pub. Date: Jul. 30, 2026

(54) ABNORMAL VOLTAGE PROTECTION CIRCUIT, SIGNAL TRANSMISSION DEVICE COMPRISING ABNORMAL VOLTAGE PROTECTION CIRCUIT, ELECTRONIC EQUIPMENT COMPRISING SIGNAL TRANSMISSION DEVICE, AND VEHICLE COMPRISING ELECTRONIC EQUIPMENT

(71) Applicant: ROHM CO., LTD., Kyoto-shi (JP)

(72) Inventor: Koki MISHIMA, Kyoto-shi (JP)

(21) Appl. No.: 19/573,603

(22) Filed: Mar. 20, 2026

Related U.S. Application Data
(63) Continuation of application No. PCT/JP2024/031027, filed on Aug. 29, 2024.

(30) Foreign Application Priority Data
Sep. 22, 2023 (JP) 2023-158459

(51) Int. Cl. H02H 3/20

(52) U.S. Cl. CPC H02H 3/207

(57) ABSTRACT

An abnormal voltage protection circuit 502 includes a voltage-current conversion circuit 507, 511, a current-voltage conversion circuit, and an abnormal voltage detection circuit C3, C4. The voltage-current conversion circuit 507, 511 is configured to convert a monitor target voltage VEE2 that is negative with respect to a reference voltage into a current signal I1, I3. The current-voltage conversion circuit is configured to convert the current signal I1, I3 into a voltage signal V7, V11 that is positive with respect to the reference voltage. The abnormal voltage detection circuit C3, C4 is configured to compare the voltage signal V7, V11 with a threshold value voltage V8, V12, so as to be able to detect the monitor target voltage VEE2 is an upper limit voltage V8 or higher, or a lower limit voltage V12 or lower.

### CROSS REFERENCE TO RELATED APPLICATIONS

This application is a continuation under 35 U.S.C. § 120 of PCT/JP2024/031027 filed on Aug. 29, 2024, which is incorporated herein by reference, and which claimed priority to Japanese Patent Application No. 2023-158459 filed on Sep. 22, 2023, the entire contents of which are hereby incorporated by reference.

### TECHNICAL FIELD

The invention disclosed in this specification relates to an abnormal voltage protection circuit, a signal transmission device including the abnormal voltage protection circuit, an electronic device including the signal transmission device, and a vehicle including the electronic device.

### BACKGROUND ART

Conventionally, a signal transmission device, which transmits a pulse signal while insulating between input and output, is used for various applications (a power supply device, a motor driving device, and the like). Such a signal transmission device may be equipped with an abnormal voltage protection circuit, which monitors a power supply voltage, and protects circuits in the signal transmission device if an abnormal state (an overvoltage state or a low voltage state) has occurred.

Note that as an example of a conventional technique related to the above description, there is Patent Document 1.

### LIST OF CITATIONS

### Patent Literature

Patent Document 1: JP-A-2022-071390

### BRIEF DESCRIPTION OF DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram illustrating a basic configuration of an electronic device equipped with a signal transmission device of the present disclosure.

FIG. 11 is a diagram illustrating an internal configuration of a first overvoltage protection circuit.

FIG. 12 is a diagram illustrating an internal configuration of a first low voltage malfunction prevention circuit.

FIG. 13 is a diagram illustrating an internal configuration of a second overvoltage protection circuit.

FIG. 14 is a diagram illustrating an internal configuration of a second low voltage malfunction prevention circuit.

FIG. 15 is a diagram illustrating a configuration of the second overvoltage protection circuit including a transistor.

FIG. 16 is a block diagram illustrating an implementation example of the signal transmission device of the present disclosure.

### DESCRIPTION OF EMBODIMENTS

### Signal Transmission Device (Basic Configuration)

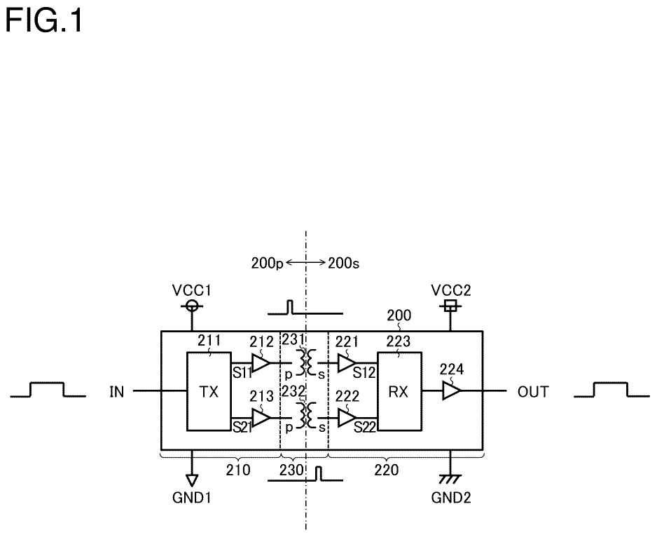

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts), and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

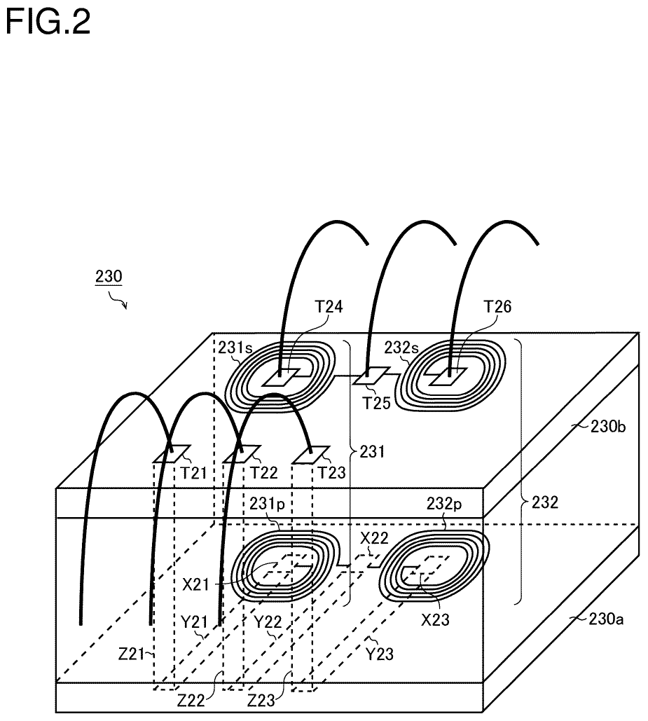

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230, and is DC-isolated from the controller chip 210 by the transformer chip 230.

### Transformer Chip (two-channel Type)

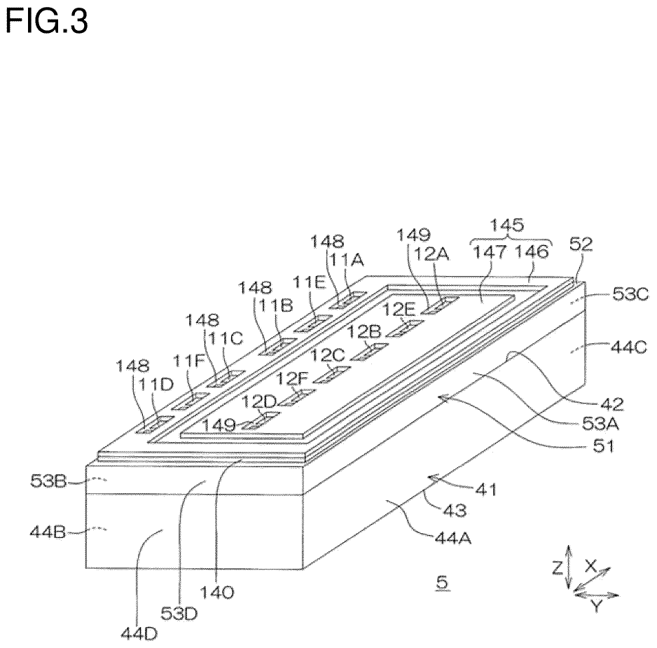

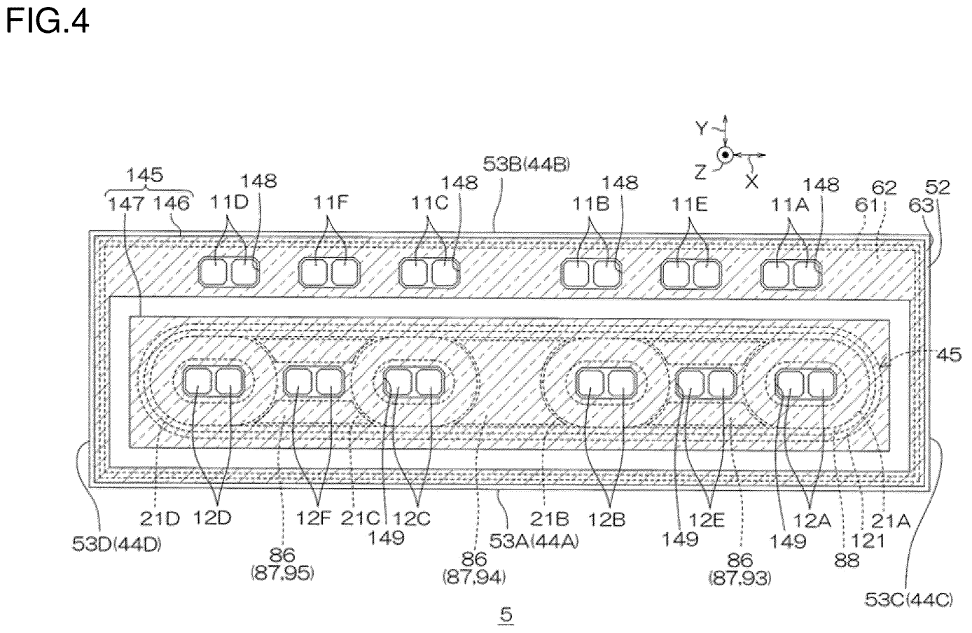

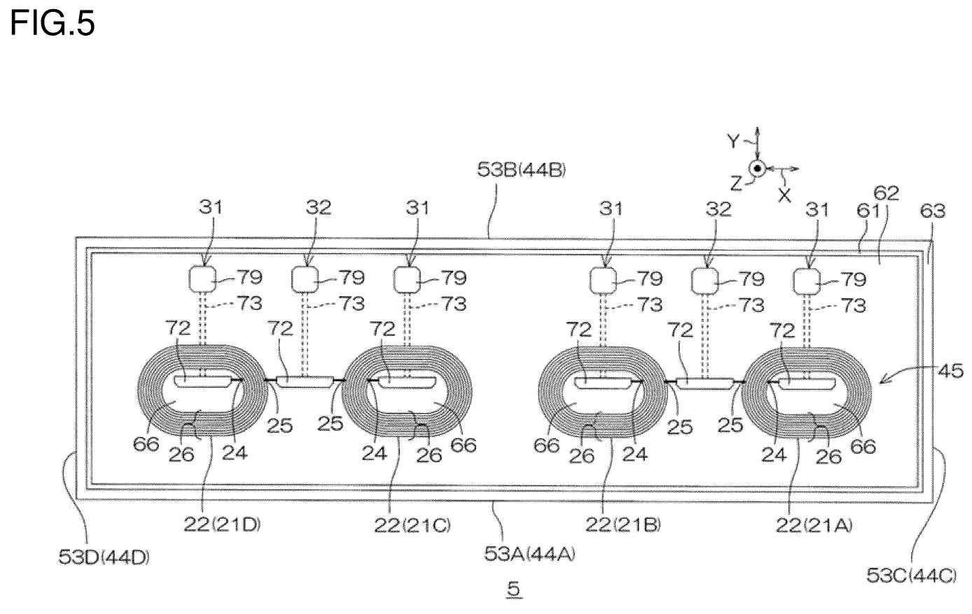

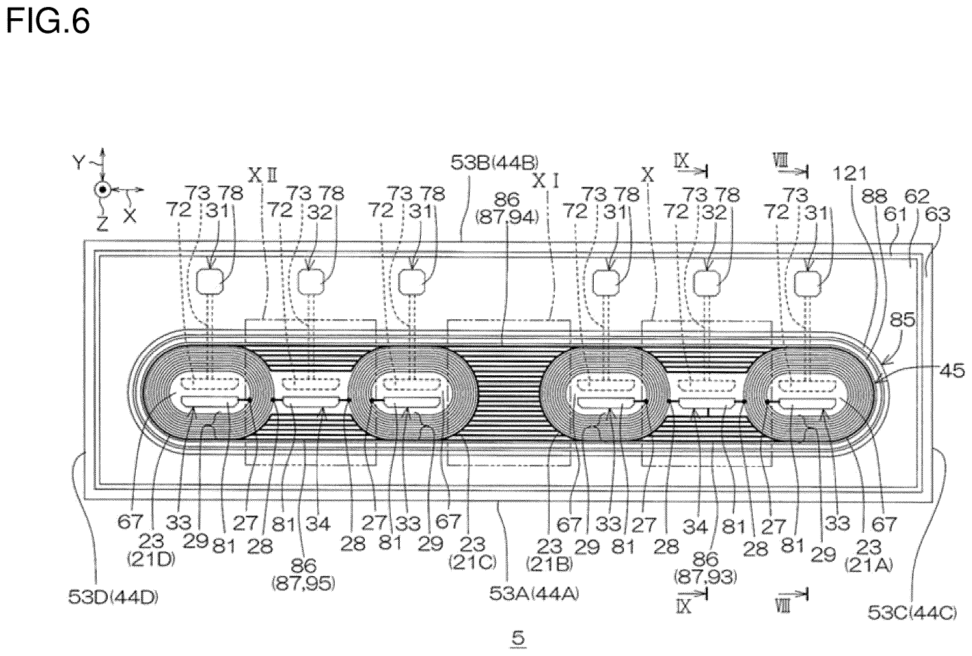

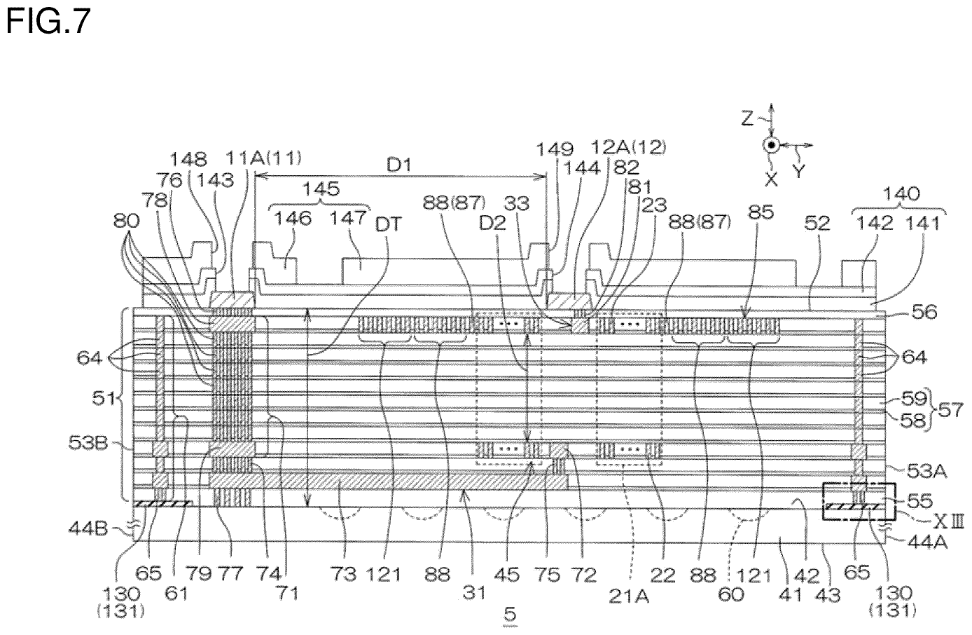

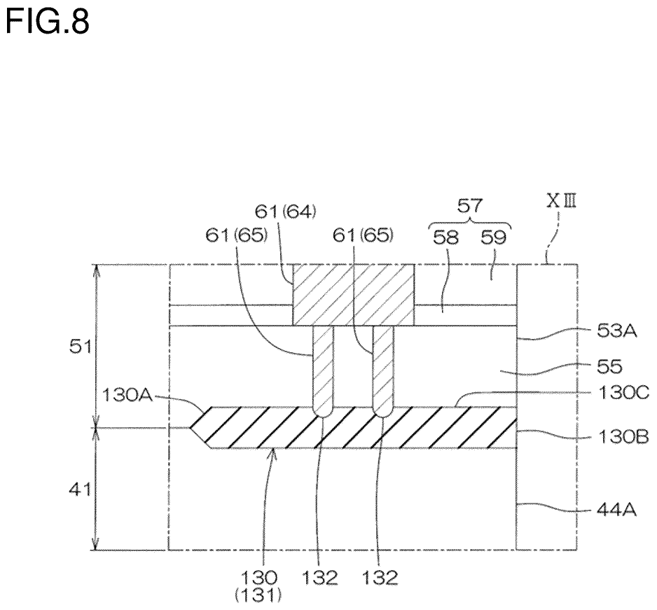

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIG. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41, and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58, and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIG. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23, and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island, and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41, and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73, and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73, and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22 and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41, and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring, and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIG. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41, and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62 as seen in a plan view. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41, and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area equal to or larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41 and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146, and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low-and high-potential terminals 11 and 12, it is possible to suppress unnecessary conduction between the high-potential terminal 12 and the sealing conductor 61. Likewise, in a case where a voltage is applied to the second functional device 60 via the low-and high-potential terminals 11 and 12, it is possible to suppress unnecessary conduction between the low-potential terminal 11 and the sealing conductor 61.

The embodiment described above deals with an example where a second functional device 60 is formed. The second functional device 60 however is not essential, and can be omitted.

The embodiment described above deals with an example where a dummy pattern 85 is formed. The dummy pattern 85 however is not essential, and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

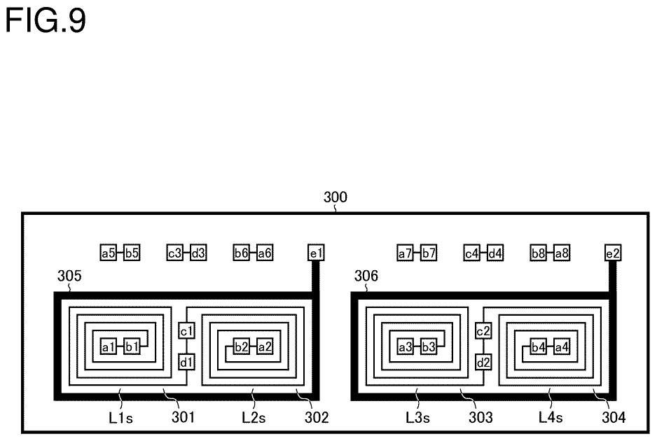

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively, and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are however not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Consideration about Abnormal Voltage Protection Function

The above signal transmission device 200 includes an abnormal voltage protection circuit for a positive power supply voltage (the above power supply voltage VCC2) of the secondary circuit system 200s. The abnormal voltage protection circuit includes an overvoltage protection circuit and a low voltage malfunction suppression circuit.

The overvoltage protection circuit is a circuit that stops power supply from the positive power supply voltage, when the positive power supply voltage to be a monitor target exceeds a predetermined upper limit value, so as to protect circuits that receive power supply from the positive power supply. The low voltage malfunction suppression circuit is a circuit that stops power supply from the positive power supply voltage, when the positive power supply voltage to be a monitor target has decreased lower than a predetermined lower limit value, so as to suppress malfunction of circuits that receive power supply from the positive power supply.

The above overvoltage protection circuit includes an overvoltage detection circuit that detects an overvoltage state. In addition, the above low voltage malfunction prevention circuit includes a low voltage detection circuit that detects a low voltage state. Each of the overvoltage detection circuit and the low voltage detection circuit compares the upper limit value or the lower limit value with a voltage value of the positive power supply voltage to be a monitor target, so as to detect the overvoltage state or the low voltage state.

Here, the above signal transmission device 200 may be configured to receive power supply from the positive power supply voltage (a voltage that is positive with respect to a reference voltage), and from a negative power supply voltage (a voltage that is negative with respect to the reference voltage). The reference voltage can be, for example, a ground voltage. In this configuration, the above abnormal voltage protection circuit is mounted in which the positive power supply voltage is a monitor target. For this reason, the upper limit value and the lower limit value are both a positive voltage value with respect to a reference voltage. Then, it is relatively easy to generate voltages of the upper limit value and the lower limit value to be used for the overvoltage detection circuit and the low voltage detection circuit, respectively.

On the other hand, when mounting the abnormal voltage protection circuit in which the negative power supply voltage is a monitor target, the upper limit value and the lower limit value are both a negative voltage value with respect to a reference voltage. Then, it is necessary to generate negative voltages as the upper limit value and the lower limit value. For this reason, a circuit configuration of the abnormal voltage protection circuit may be complicated.

For this problem, an abnormal voltage protection circuit 502 of the present disclosure can be mounted on the above signal transmission device 200, in which the negative power supply voltage is a monitor target. Further, the abnormal voltage protection circuit 502 has a relatively simple configuration, and can detect whether or not the monitor target voltage is in an abnormal state (an overvoltage state where it exceeds the upper limit value, or a low voltage state where it is less than the lower limit value). For this reason, it is possible to suppress the circuit configuration from being complicated as described above. Hereinafter, the abnormal voltage protection circuit 502 according to an embodiment of the present disclosure is described in detail. Note that the signal transmission device 200 including the abnormal voltage protection circuit 502, and an electronic device 400 including the signal transmission device 200 are exemplified and described.

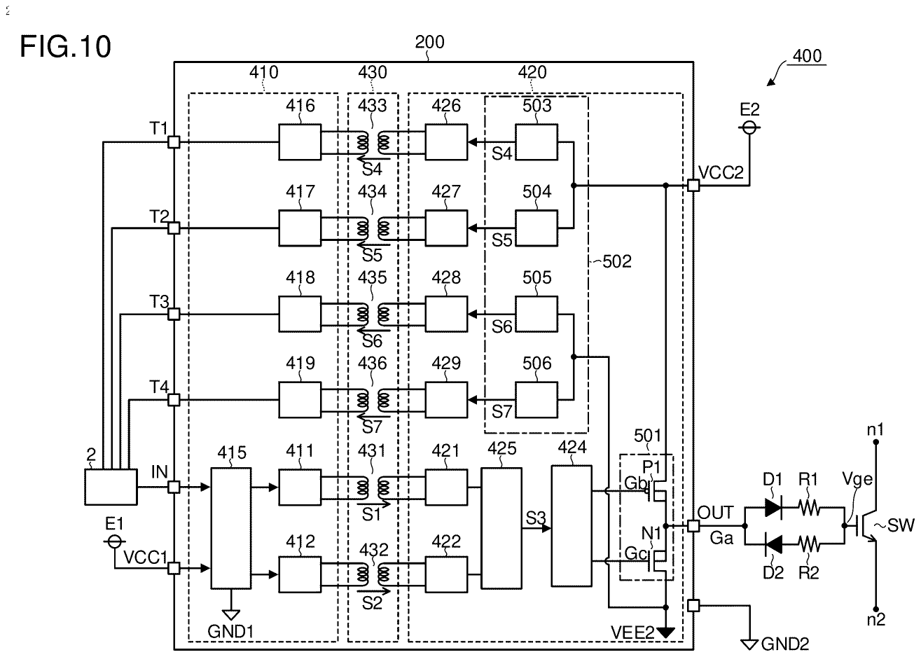

FIG. 10 is a diagram illustrating a basic configuration of the electronic device 400 in which the signal transmission device 200 of the present disclosure is mounted. The electronic device 400 of this configuration example is one type of a motor driving device, which converts a DC power supplied from a not-shown in-vehicle battery into an AC power, so as to drive a motor M (see FIG. 16 mentioned later).

As illustrated in FIG. 10, the electronic device 400 includes the signal transmission device 200, an ECU (electronic control unit) 2, and a plurality of discrete components (a switching element SW, diodes D1 and D2, and resistors R1 and R2).

The signal transmission device 200 is a semiconductor integrated circuit device. The signal transmission device 200 is configured to transmit gate drive signals from a primary circuit system (VCC1-GND1) to a secondary circuit system (VCC2-VEE2), while insulating between the primary circuit system and the secondary circuit system.

The signal transmission device 200 has a plurality of external terminals (a terminal VCC1, a terminal IN, a terminal VCC2, a terminal OUT, first to fourth detection signal output terminals T1 to T4, in this diagram), as means for establishing electrical connection with outside of the device.

The terminal VCC1 is a power supply terminal of the primary circuit system. The primary circuit system receives power supply from a voltage source E1 via the terminal VCC1. The terminal VCC2 is a power supply terminal of the secondary circuit system. The secondary circuit system receives power supply from a voltage source E2 via the terminal VCC2.

The terminal IN is a control input terminal. The terminal IN receives an input signal IN from the ECU 2. The ECU 2 is a means for integrally performing electric control of the motor driving device and a vehicle in which the motor driving device is mounted. The ECU 2 drives the input signal IN by switching the signal level between high level (with respect to VCC1) and low level (with respect to GND1).

The terminal OUT is an output terminal for outputting a drive signal Ga for driving the switching element SW. The terminal OUT is connected to a gate terminal of the switching element SW via the resistors R1 and R2, and the diodes D1 and D2.

The drive signal Ga of high level (with respect to VCC2) or low level (with respect to VEE2) is output from the terminal OUT.

As the switching element SW, it is suitable to use a power semiconductor element such as an IGBT, a power MOSFET (Metal Oxide Semiconductor Field Effect Transistor), an SiC-MOSFET (Silicon Carbide-Metal Oxide Semiconductor FET), an SiC-SIT (SiC-Static Induction Transistor), or a GaN-MOSFET (Gallium Nitride-MOSFET), which can work at high frequency. As illustrated in FIG. 10, in the electronic device 400, an IGBT is used as the switching element SW.

A gate signal Vge that is input to a gate terminal of the switching element SW changes in accordance with the drive signal Ga. In other words, the signal transmission device 200 performs drive control of the switching element SW using the drive signal Ga.

Specifically, when the gate signal Vge is at high level (when it exceeds a threshold value voltage of the switching element SW), the switching element SW is turned on. When the gate signal Vge is at low level (when it is lower than or equal to the threshold value voltage of the switching element SW), the switching element SW is turned off.

The collector of the switching element SW is connected to a node n1. The emitter of the switching element SW is connected to a node n2. Note that a specific example of the nodes n1 and n2 will be described later.

### Internal Configuration of Signal Transmission Device 200

Next, an internal configuration of the signal transmission device 200 is described in detail. The signal transmission device 200 includes a first semiconductor chip 410, a second semiconductor chip 420, and a third semiconductor chip 430, which are sealed in one package.

The first semiconductor chip 410 corresponds to the above-mentioned primary circuit system 200p. The first semiconductor chip 410 is a controller chip in which controllers having generation functions of the signals are integrated. The first semiconductor chip 410 is driven by being supplied with the power supply voltage VCC1 from the voltage source E1. The first semiconductor chip 410 generates a first internal signal S1 and a second internal signal S2 on the basis of the input signal IN.

The second semiconductor chip 420 corresponds to the above-mentioned secondary circuit system 200s. The second semiconductor chip 420 is a driver chip in which drivers for drive control of the switching element SW are integrated. The second semiconductor chip 420 is driven by being supplied with the power supply voltage VCC2 from the voltage source E2. The second semiconductor chip 420 receives the first internal signal S1 and the second internal signal S2 from the first semiconductor chip 410 via the third semiconductor chip 430. The second semiconductor chip 420 generates the drive signal Ga on the basis of the first internal signal S1 and the second internal signal S2.

The third semiconductor chip 430 is a transformer chip, in which a plurality of transformers (a first transformer 431, a second transformer 432, a third transformer 433, a fourth transformer 434, a fifth transformer 435, and a sixth transformer 436, with reference to FIG. 10) are integrated. The third semiconductor chip 430 transmits the first internal signal S1 and the second internal signal S2, while providing DC insulation between the first semiconductor chip 410 and the second semiconductor chip 420.

The first semiconductor chip 410 includes a logic circuit 415, a first transmission circuit 411, and a second transmission circuit 412.

The logic circuit 415 receives the input signal IN input from the ECU 2, so as to generate the first internal signal S1 and the second internal signal S2, which are input to the first transmission circuit 411 and the second transmission circuit 412, respectively.

The first transmission circuit 411 sends the first internal signal S1, which is input from the logic circuit 415, to a first reception circuit 421 via the first transformer 431.

The second transmission circuit 412 sends the second internal signal S2, which is input from the logic circuit 415, to a second reception circuit 422 via the second transformer 432.

The second semiconductor chip 420 includes the first reception circuit 421, the second reception circuit 422, a logic circuit 425, a driver circuit 424, and an output circuit 501.

The first reception circuit 421 receives the first internal signal S1 from the first transmission circuit 411 via the first transformer 431, and inputs the same to the logic circuit 425.

The second reception circuit 422 receives the second internal signal S2 from the second transmission circuit 412 via the second transformer 432, and inputs the same to the logic circuit 425.

On the basis of the inputs of the first internal signal S1 and the second internal signal S2, the logic circuit 425 generates a driver control signal S3, and inputs the same to the driver circuit 424.

On the basis of the input driver control signal S3, the driver circuit 424 generates drive signals Gb and Gc. The driver circuit 424 controls the output circuit 501 by the drive signals Gb and Gc.

The output circuit 501 includes a transistor P1 and a transistor N1. The transistor P1 is a P-channel type MOSFET. The transistor N1 is an N-channel type MOSFET.

The source of the transistor P1 is connected to the terminal VCC2. The drains of the transistors P1 and N1 are both connected to the terminal OUT. The source of the transistor N1 is connected to a connection terminal of VEE2. The gates of the transistors P1 and N1 are connected to the driver circuit 424.

The drive signal Gb is input to the gate terminal of the transistor P1. The transistor P1 is on/off controlled by the drive signal Gb. The drive signal Gc is input to the gate terminal of the transistor N1. The transistor N1 is on/off controlled by the drive signal Gc. In accordance with on/off states of the transistors P1 and N1, the drive signal Ga of high level (with respect to VCC2) or low level (with respect to VEE2) is output from the terminal OUT.

Next, a basic operation of the signal transmission device 200 is described. It is supposed that the input signal IN of high level is input from the ECU 2 to the terminal IN. Then, the logic circuit 415 generates a pulse on the first internal signal S1. Specifically, the logic circuit 415 detects a positive edge (a rising edge from low level to high level) of the input signal IN, and sets a pulse on the first internal signal S1.

On the contrary, it is supposed that the input signal IN of low level is input from the ECU 2 to the terminal IN. Then, the logic circuit 415 generates a pulse on the second internal signal S2. Specifically, the logic circuit 415 detects a negative edge (a falling edge from high level to low level) of the input signal IN, and sets a pulse on the second internal signal S2.

When the logic circuit 425 receives the pulse of the first internal signal S1, it raises the driver control signal S3 to high level. On the contrary, when the logic circuit 425 receives the pulse of the second internal signal S2, it lowers the driver control signal S3 to low level.

When the driver circuit 424 receives the driver control signal S3 of high level, it decreases the drive signal Gb to low level, and decreases the drive signal Gc to low level. In this way, the transistor P1 is turned on, and the transistor N1 is turned off. Therefore, the drive signal Ga of high level (with respect to VCC2) is output from the terminal OUT.

On the contrary, when the driver circuit 424 receives the driver control signal S3 of low level, it raises the drive signal Gb to high level, and raises the drive signal Gc to high level. In this way, the transistor P1 is turned off, and the transistor N1 is turned on. Therefore, the drive signal Ga of low level (with respect to VEE2) is output from the terminal OUT.

### Abnormal Voltage Protection Circuit 502

Next, a configuration of the abnormal voltage protection circuit 502 is described.

In addition to the above configuration, the second semiconductor chip 420 includes the abnormal voltage protection circuit 502, a third transmission circuit 426, a fourth transmission circuit 427, a fifth transmission circuit 428, and a sixth transmission circuit 429.

The abnormal voltage protection circuit 502 includes a first overvoltage protection circuit 503, a first low voltage malfunction prevention circuit 504, a second overvoltage protection circuit 505, and a second low voltage malfunction prevention circuit 506.

The first overvoltage protection circuit 503 monitors the positive power supply voltage VCC2, so as to detect whether or not the positive power supply voltage VCC2 is in the overvoltage state, and generates a detection signal S4 corresponding to a detection result. The first overvoltage protection circuit 503 inputs the detection signal S4 to the third transmission circuit 426.

The first low voltage malfunction prevention circuit 504 monitors the positive power supply voltage VCC2, so as to detect whether or not the positive power supply voltage VCC2 is in the low voltage state, and generates a detection signal S5 corresponding to a detection result. The first low voltage malfunction prevention circuit 504 inputs the detection signal S5 to the fourth transmission circuit 427. Detailed configurations of the first overvoltage protection circuit 503 and the first low voltage malfunction prevention circuit 504 will be described later.

The second overvoltage protection circuit 505 monitors the negative power supply voltage VEE2, so as to detect whether or not the negative power supply voltage VEE2 is in the overvoltage state, and generates a detection signal S6 corresponding to a detection result. The second overvoltage protection circuit 505 inputs the detection signal S6 to the fifth transmission circuit 428.

The second low voltage malfunction prevention circuit 506 monitors the negative power supply voltage VEE2, so as to detect whether or not the negative power supply voltage VEE2 is in the low voltage state, and generates a detection signal S7 corresponding to a detection result. The second low voltage malfunction prevention circuit 506 inputs the detection signal S7 to the sixth transmission circuit 429. Detailed configuration of the second overvoltage protection circuit 505 and the second low voltage malfunction prevention circuit 506 will be described later.

The third transmission circuit 426 inputs the detection signal S4 to the third semiconductor chip 430 (more specifically, to the third transformer 433 described later). The fourth transmission circuit 427 inputs the detection signal S5 to the third semiconductor chip 430 (more specifically, to the fourth transformer 434 described later). The fifth transmission circuit 428 inputs the detection signal S6 to the third semiconductor chip 430 (more specifically, to the fifth transformer 435 described later). The sixth transmission circuit 429 inputs the detection signal S7 to the third semiconductor chip 430 (more specifically, to the sixth transformer 436 described later).

In addition to the above configuration, the third semiconductor chip 430 includes the third transformer 433, the fourth transformer 434, the fifth transformer 435, and the sixth transformer 436.

The third transformer 433 transmits the input detection signal S4 to the first semiconductor chip 410 (more specifically, a third reception circuit 416 described later). The fourth transformer 434 transmits the input detection signal S5 to the first semiconductor chip 410 (more specifically, a fourth reception circuit 417 described later). The fifth transformer 435 transmits the input detection signal S6 to the first semiconductor chip 410 (more specifically, a fifth reception circuit 418 described later). The sixth transformer 436 transmits the input detection signal S7 to the first semiconductor chip 410 (more specifically, a sixth reception circuit 419 described later).

In addition to the above configuration, the first semiconductor chip 410 includes the third reception circuit 416, the fourth reception circuit 417, the fifth reception circuit 418, and the sixth reception circuit 419.

The third reception circuit 416 receives the detection signal S4 from the third transformer 433. The third reception circuit 416 outputs the received detection signal S4 to the outside via the first detection signal output terminal T1. The fourth reception circuit 417 receives the detection signal S5 from the fourth transformer 434. The fourth reception circuit 417 outputs the received detection signal S5 to the outside via the second detection signal output terminal T2. The fifth reception circuit 418 receives the detection signal S6 from the fifth transformer 435. The fifth reception circuit 418 outputs the received detection signal S6 to the outside via the third detection signal output terminal T3. The sixth reception circuit 419 receives the detection signal S7 from the sixth transformer 436. The sixth reception circuit 419 outputs the received detection signal S7 to the outside via the fourth detection signal output terminal T4.

The ECU 2 is connected to the first to fourth detection signal output terminals T1 to T4. The ECU 2 receives the detection signals S4 to S7 output from the first to fourth detection signal output terminals T1 to T4. The ECU 2 controls the signal transmission device 200 in accordance with respective signal levels of the received detection signals S4 to S7.

### Operation of Abnormal Voltage Protection Circuit 502

Next, an operation of the abnormal voltage protection circuit 502 is described specifically.

When the first overvoltage protection circuit 503 detects the overvoltage state of the positive power supply voltage VCC2, it raises the detection signal S4 to high level. On the contrary, when the first overvoltage protection circuit 503 does not detect the overvoltage state of the positive power supply voltage VCC2, it sets the detection signal S4 to low level.

As described above, the ECU 2 receives the detection signal S4 via the third transmission circuit 426, the third transformer 433, and the third reception circuit 416. When the received detection signal S4 is at high level (when the positive power supply voltage VCC2 is in the overvoltage state), the ECU 2 inputs the control signal to the terminal IN so that the transistors P1 and N1 are both turned off.

When the first low voltage malfunction prevention circuit 504 detects the low voltage state of the positive power supply voltage VCC2, it raises the detection signal S5 to high level. On the contrary, when the first low voltage malfunction prevention circuit 504 does not detect the low voltage state of the positive power supply voltage VCC2, it sets the detection signal S5 to low level.

As described above, the ECU 2 receives the detection signal S5 via the fourth transmission circuit 427, the fourth transformer 434, and the fourth reception circuit 417. When the received detection signal S5 is at high level (when the positive power supply voltage VCC2 is in the low voltage state), the ECU 2 inputs the control signal to the terminal IN so that the transistors P1 and N1 are both turned off.

When the second overvoltage protection circuit 505 detects the overvoltage state of the negative power supply voltage VEE2, it raises the detection signal S6 to high level. On the contrary, when the second overvoltage protection circuit 505 does not detect the overvoltage state of the negative power supply voltage VEE2, it sets the detection signal S6 to low level.

As described above, the ECU 2 receives the detection signal S6 via the fifth transmission circuit 428, the fifth transformer 435, and the fifth reception circuit 418. When the received detection signal S6 is at high level (when the negative power supply voltage VEE2 is in the overvoltage state), the ECU 2 inputs the control signal to the terminal IN so that the transistors P1 and N1 are both turned off.

When the second low voltage malfunction prevention circuit 506 detects the low voltage state of the negative power supply voltage VEE2, it raises the detection signal S7 to high level. On the contrary, when the second low voltage malfunction prevention circuit 506 does not detect the low voltage state of the negative power supply voltage VEE2, it sets the detection signal S7 to low level.

As described above, the ECU 2 receives the detection signal S7 via the sixth transmission circuit 429, the sixth transformer 436, and the sixth reception circuit 419. When the received detection signal S7 is at high level (when the negative power supply voltage VEE2 is in the low voltage state), the ECU 2 inputs the control signal to the terminal IN so that the transistors P1 and N1 are both turned off.

On the other hand, when the received detection signals S4 to S7 are all at low level, the ECU 2 inputs the control signal to the terminal IN so that the transistors P1 and N1 are normally driven.

### More Detailed Configuration of Abnormal Voltage Protection Circuit 502

Next described is a more detailed configuration of the abnormal voltage protection circuit 502 (specifically, the first overvoltage protection circuit 503, the first low voltage malfunction prevention circuit 504, the second overvoltage protection circuit 505, and the second low voltage malfunction prevention circuit 506).

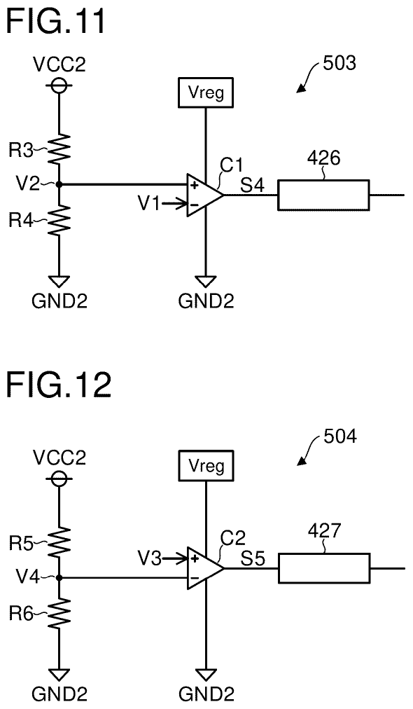

FIG. 11 is a diagram illustrating an internal configuration of the first overvoltage protection circuit 503. The first overvoltage protection circuit 503 includes resistors R3 and R4, and a first overvoltage detection circuit C1.

A first terminal of the resistor R3 is connected to an application terminal of the positive power supply voltage VCC2. A second terminal of the resistor R3 is connected to a noninverting input terminal (+) of the first overvoltage detection circuit C1, together with a first terminal of the resistor R4. A second terminal of the resistor R4 is connected to a ground terminal GND2.

The noninverting input terminal (+) of the first overvoltage detection circuit C1 is applied with a divided voltage V2 obtained by dividing the positive power supply voltage VCC2 by the resistors R3 and R4. An inverting input terminal (−) of the first overvoltage detection circuit C1 is applied with a first upper limit voltage V1. The first overvoltage detection circuit C1 is supplied with a constant voltage Vreg as a high side drive power supply. In addition, the first overvoltage detection circuit C1 is supplied with a ground voltage GND2 as a low side drive power supply.

The first overvoltage detection circuit C1 compares voltages input to the noninverting input terminal (+) and the inverting input terminal (−), respectively, and generates the detection signal S4 of high level or low level in accordance with a comparison result. Specifically, if the divided voltage V2 is the first upper limit voltage V1 or higher, the first overvoltage detection circuit C1 outputs the detection signal S4 of high level. On the contrary, if the divided voltage V2 is lower than the first upper limit voltage V1, the first overvoltage detection circuit C1 outputs the detection signal S4 of low level.

FIG. 12 is a diagram illustrating an internal configuration of the first low voltage malfunction prevention circuit 504. The first low voltage malfunction prevention circuit 504 includes resistors R5 and R6, and a first low voltage detection circuit C2.

A first terminal of the resistor R5 is connected to an application terminal of the positive power supply voltage VCC2. A second terminal of the resistor R5 is connected to an inverting input terminal (−) of the first low voltage detection circuit C2, together with a first terminal of the resistor R6. A second terminal of the resistor R6 is connected to the ground terminal GND2.

A noninverting input terminal (+) of the first low voltage detection circuit C2 is applied with a first lower limit voltage V3. The inverting input terminal (−) of the first low voltage detection circuit C2 is applied with a divided voltage V4 obtained by dividing the positive power supply voltage VCC2 by the resistors R5 and R6. The first low voltage detection circuit C2 is supplied with the constant voltage Vreg as the high side drive power supply. In addition, the first low voltage detection circuit C2 is supplied with the ground voltage GND2 as the low side drive power supply.

The first low voltage detection circuit C2 compares voltages input to the noninverting input terminal (+) and the inverting input terminal (−), respectively, and generates the detection signal S5 of high level or low level in accordance with a comparison result. Specifically, if the first lower limit voltage V3 is the divided voltage V4 or higher (in other words, if the divided voltage V4 is lower than the first lower limit voltage V3), the first low voltage detection circuit C2 outputs the detection signal S5 of high level. On the contrary, if the first lower limit voltage V3 is lower than the divided voltage V4 (in other words, if the divided voltage V4 is the first lower limit voltage V3 or higher), the first low voltage detection circuit C2 outputs the detection signal S5 of low level.

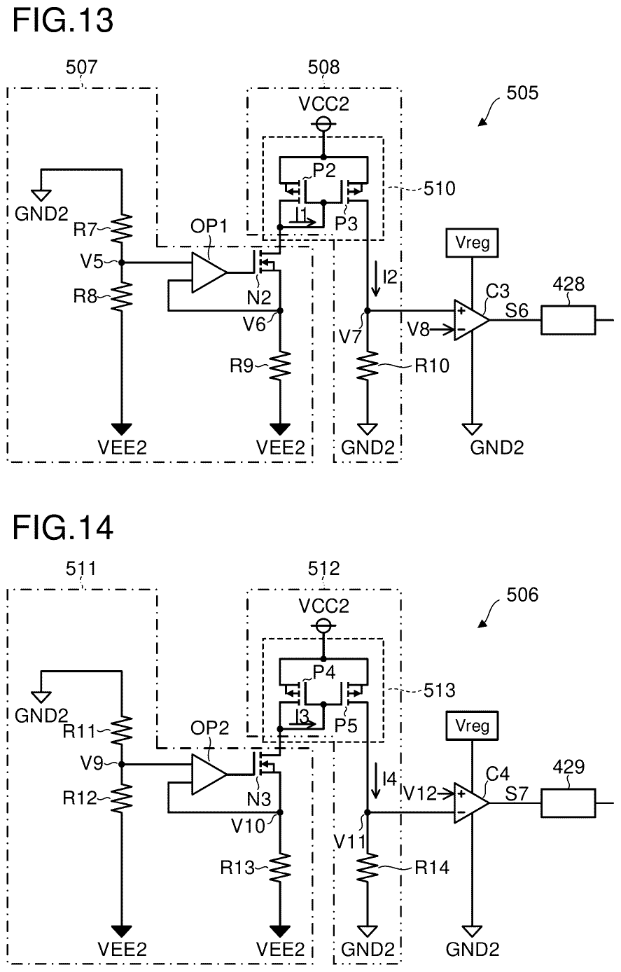

FIG. 13 is a diagram illustrating an internal configuration of the second overvoltage protection circuit 505. The second overvoltage protection circuit 505 includes a first voltage-current conversion circuit 507, a first current-voltage conversion circuit 508, and a second overvoltage detection circuit C3 (an abnormal voltage detection circuit).

The first voltage-current conversion circuit 507 converts a voltage of the negative power supply voltage VEE2 to be a monitor target into a current signal (a current I1 described later). Specifically, it is as follows.

The first voltage-current conversion circuit 507 includes resistors R7, R8, and R9, an operational amplifier OP1, and a transistor N2.

A first terminal of the resistor R7 is connected to the ground terminal GND2. A second terminal of the resistor R7 is connected to a first input terminal of the operational amplifier OP1, together with a first terminal of the resistor R8. A second terminal of the resistor R8 is connected to an application terminal of the negative power supply voltage VEE2.

The transistor N2 is an N-channel type MOSFET. The gate of the transistor N2 is connected to an output terminal of the operational amplifier OP1. The source of the transistor N2 is connected to a second input terminal of the operational amplifier OP1, together with a first terminal of the resistor R9. The drain of the transistor N2 is connected to an application terminal of the first current-voltage conversion circuit 508 (more specifically, the drain of a transistor P2, the gate of the transistor P2, and the gate of a transistor P3, as described later).

A second terminal of the resistor R9 is connected to the application terminal of the negative power supply voltage VEE2. A voltage at the connection node between the first terminal of the resistor R9 and the second input terminal of the operational amplifier OP1 is referred to as a node voltage V6.

The first input terminal of the operational amplifier OP1 is applied with a divided voltage V5. The divided voltage V5 is a voltage obtained by dividing a voltage between the ground voltage GND2 and the negative power supply voltage VEE2 by the resistor R7 and the resistor R8. The second input terminal of the operational amplifier OP1 is applied with the node voltage V6 as a feedback input.

The operational amplifier OP1 applies the gate of the transistor N2 with an output voltage corresponding to a difference voltage between an input voltage of the first input terminal (specifically, the divided voltage V5) and an input voltage of the second input terminal (specifically, the node voltage V6). A voltage across the resistor R9 (=the node voltage V6) changes in accordance with the gate voltage of the transistor N2 (=an output voltage of the operational amplifier OP1). More specifically, the operational amplifier OP1 performs drive control of the transistor N2 so that the divided voltage V5 and the node voltage V6 agree with each other, by the feedback input of the node voltage V6. As described above, the current I1 is generated corresponding to the negative power supply voltage VEE2 and a resistance value of the resistor R9. The current I1 is input as a current signal to the first current-voltage conversion circuit 508.

The first current-voltage conversion circuit 508 converts the input current signal (the current I1 with reference to this diagram) into a voltage signal (a node voltage V7 described later). Specifically, it is as follows. The first current-voltage conversion circuit 508 includes a current mirror circuit 510 and a resistor R10.

The current mirror circuit 510 generates a mirror current (a current I2 with reference to this diagram) that mirrors an input current (the current I1 with reference to this diagram).

The current mirror circuit 510 includes the transistors P2 and P3. The transistors P2 and P3 are each a P-channel type MOSFET. Each gate of the transistors P2 and P3 is connected to the drain of the transistor N2, together with the drain of the transistor P2. The source of the transistor P2 is connected to the application terminal of the positive power supply voltage VCC2, together with the source of the transistor P3. The drain of the transistor P3 is connected to a noninverting input terminal (+) of the second overvoltage detection circuit C3, together with a first terminal of the resistor R10.

A second terminal of the resistor R10 is connected to the ground terminal GND2. A voltage at a connection node between the first terminal of the resistor R10 and the noninverting input terminal (+) of the second overvoltage detection circuit C3 is referred to as the node voltage V7. When the current I2 flows in the resistor R10, a voltage across the resistor R10 (=the node voltage V7) is generated.

The noninverting input terminal (+) of the second overvoltage detection circuit C3 is applied with the node voltage V7. An inverting input terminal (−) of the second overvoltage detection circuit C3 is applied with a second upper limit voltage V8. The second overvoltage detection circuit C3 is supplied with the constant voltage Vreg as the high side drive power supply. In addition, the second overvoltage detection circuit C3 is supplied with the ground voltage GND2 as the low side drive power supply.

The second overvoltage detection circuit C3 compares voltages input to the noninverting input terminal (+) and the inverting input terminal (−), so as to output the detection signal S6 of high level or low level, in accordance with a comparison result. Specifically, if the node voltage V7 is the second upper limit voltage V8 or higher, the second overvoltage detection circuit C3 outputs the detection signal S6 of high level. On the contrary, if the node voltage V7 is lower than the second upper limit voltage V8, the second overvoltage detection circuit C3 outputs the detection signal S6 of low level.

FIG. 14 is a diagram illustrating an internal configuration of the second low voltage malfunction prevention circuit 506. The second low voltage malfunction prevention circuit 506 includes a second voltage-current conversion circuit 511, a second current-voltage conversion circuit 512, and the second low voltage detection circuit C4 (an abnormal voltage detection circuit).

The second voltage-current conversion circuit 511 converts the negative power supply voltage VEE2 to be a monitor target into a current signal (a current I3 described later). Specifically, it is as follows.

The second voltage-current conversion circuit 511 includes resistors R11, R12, and R13, an operational amplifier OP2, and a transistor N3.

A first terminal of the resistor R11 is connected to the ground terminal GND2. A second terminal of the resistor R11 is connected to a first input terminal of the operational amplifier OP2, together with a first terminal of the resistor R12. A second terminal of the resistor R12 is connected to the application terminal of the negative power supply voltage VEE2.

The transistor N3 is an N-channel type MOSFET. The gate of the transistor N3 is connected to an output terminal of the operational amplifier OP2. The source of the transistor N3 is connected to a second input terminal of the operational amplifier OP2, together with a first terminal of the resistor R13. The drain of the transistor N3 is connected to an application terminal of the second current-voltage conversion circuit 512 (more specifically, the drain of a transistor P4 described later, the gate of the transistor P4, and the gate of a transistor P5).

A second terminal of the resistor R13 is connected to the application terminal of the negative power supply voltage VEE2. A voltage at a connection node between the first terminal of the resistor R13 and the second input terminal of the operational amplifier OP2 is referred to as a node voltage V10.

The first input terminal of the operational amplifier OP2 is applied with a divided voltage V9. The divided voltage V9 is a voltage obtained by dividing a voltage between the ground voltage GND2 and the negative power supply voltage VEE2 by the resistor R11 and the resistor R12. The second input terminal of the operational amplifier OP2 is applied with the node voltage V10 as a feedback input.

The operational amplifier OP2 applies the gate of the transistor N3 with an output voltage corresponding to a difference voltage between an input voltage of the first input terminal (specifically, the divided voltage V9) and an input voltage of the second input terminal (specifically, the node voltage V10). More specifically, the operational amplifier OP2 performs drive control of the transistor N3 so that the divided voltage V9 and the node voltage V10 agree with each other, by the feedback input of the node voltage V10. As described above, the current I3 is generated corresponding to the negative power supply voltage VEE2 and a resistance value of the resistor R13. The current I3 is input as a current signal to the second current-voltage conversion circuit 512.

The second current-voltage conversion circuit 512 converts the input current signal (the current I3 with reference to this diagram) into a voltage signal (a node voltage V11 described later). Specifically, it is as follows. The second current-voltage conversion circuit 512 includes a current mirror circuit 513 and a resistor R14.

The current mirror circuit 513 generates a current I4 obtained by mirroring an input current (the current I3 with reference to this diagram). A specific configuration of the current mirror circuit 513 is as follows.

The current mirror circuit 513 includes the transistors P4 and P5. The transistors P4 and P5 are each a P-channel type MOSFET. Each gate of the transistors P4 and P5 is connected to the drain of the transistor N3, together with the drain of the transistor P4. The source of the transistor P4 is connected to the application terminal of the positive power supply voltage VCC2, together with the source of the transistor P5. The drain of the transistor P5 is connected to an inverting input terminal (−) of the second low voltage detection circuit C4, together with a first terminal of the resistor R14.

A second terminal of the resistor R14 is connected to the ground terminal GND2. A voltage at a connection node between the first terminal of the resistor R14 and the inverting input terminal (−) of the second low voltage detection circuit C4 is referred to as the node voltage V11. When the current I4 flows in the resistor R14, a voltage across the resistor R14 (=the node voltage V11) is generated.

A noninverting input terminal (+) of the second low voltage detection circuit C4 is applied with a second lower limit voltage V12. The inverting input terminal (−) of the second low voltage detection circuit C4 is applied with the node voltage V11. The second low voltage detection circuit C4 is supplied with the constant voltage Vreg as the high side drive power supply. In addition, the second low voltage detection circuit C4 is supplied with the ground voltage GND2 as the low side drive power supply.

The second low voltage detection circuit C4 compares voltages input to the noninverting input terminal (+) and the inverting input terminal (−), respectively, so as to generate the detection signal S7 of high level or low level in accordance with a comparison result. Specifically, if the second lower limit voltage V12 is the node voltage V11 or higher (in other words, if the node voltage V11 is lower than the second lower limit voltage V12), the second low voltage detection circuit C4 outputs the detection signal S7 of high level. On the contrary, if the second lower limit voltage V12 is lower than the node voltage V11 (in other words, if the node voltage V11 is the second lower limit voltage V12 or higher), the second low voltage detection circuit C4 outputs the detection signal S7 of low level.

As described above, the second overvoltage protection circuit 505 converts the negative power supply voltage VEE2 as a monitor target voltage into the current I1, and converts the current I1 into the node voltage V7. Then, it detects whether or not the node voltage V7 is higher than the second upper limit voltage V8, and hence can detect whether or not the negative power supply voltage VEE2 is higher than a predetermined threshold value voltage.

Further, the current I1 that is converted from the negative power supply voltage VEE2 by the first voltage-current conversion circuit 507 has a positive current value. The node voltage V7 that is converted from the current I1 by the first current-voltage conversion circuit 508 has a positive voltage value. For this reason, the second upper limit voltage V8 to be compared with the node voltage V7 has a positive value with respect to a reference voltage. The second upper limit voltage V8 can be generated relatively easily because it has positive voltage value with respect to the reference voltage. Therefore, it can detect whether or not the negative power supply voltage VEE2 is higher than a predetermined threshold value voltage, with a simple circuit configuration.

In the same manner, the second low voltage malfunction prevention circuit 506 converts the negative power supply voltage VEE2 as a monitor target voltage into the current I3, and converts the current I3 into the node voltage V11. Further, it detects whether or not the node voltage V11 has reached the second lower limit voltage V12, and hence can detect whether or not the negative power supply voltage VEE2 has reached a predetermined threshold value voltage.

Further, the current I3 that is converted from the negative power supply voltage VEE2 by the second voltage-current conversion circuit 511 has a positive current value. The node voltage V11 converted from the current I3 by the second current-voltage conversion circuit 512 has a positive voltage value. For this reason, the second lower limit voltage V12 to be compared with the node voltage V11 has a positive value with respect to a reference voltage. The second lower limit voltage V12 can be generated relatively easily because it has a positive voltage value with respect to a reference voltage. Therefore, it can detect whether or not the negative power supply voltage VEE2 has reached a predetermined threshold value voltage, with a simple circuit configuration.

### Clamp Circuit

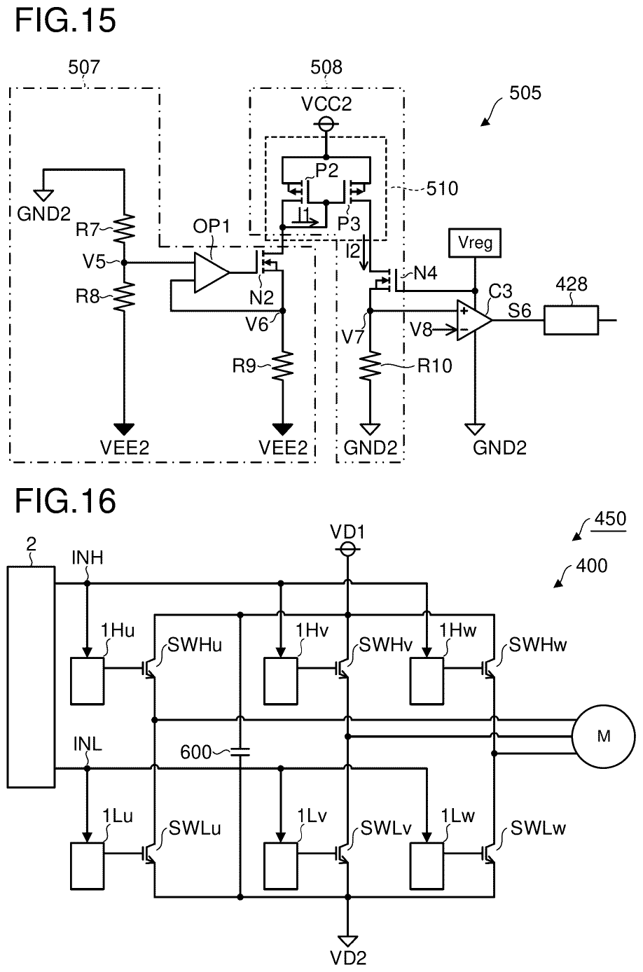

Note that each of the first current-voltage conversion circuit 508 and the second current-voltage conversion circuit 512 can have a configuration including a transistor N4 (a clamp circuit), in addition to the above configuration. This configuration is described with reference to FIG. 15, using an example where the first current-voltage conversion circuit 508 includes the transistor N4.

FIG. 15 is a diagram illustrating a configuration of the second overvoltage protection circuit 505 including the transistor N4. As illustrated in FIG. 15, the drain of the transistor N4 is connected to the drain of the transistor P3. The source of the transistor N4 is connected to the noninverting input terminal (+) of the second overvoltage detection circuit C3, together with the first terminal of the resistor R10. The gate of the transistor N4 is connected to an input terminal of the positive power supply of the second overvoltage detection circuit C3, together with an application terminal of the constant voltage Vreg.

The transistor N4 keeps the node voltage V7 to be the constant voltage Vreg or lower. More specifically, if the node voltage V7 is lower than the constant voltage Vreg, the transistor N4 is turned on so as to set the node voltage V7 to a voltage value corresponding to the output voltage of the operational amplifier OP1 (more specifically, a current value of the current I2 and a resistance value of the resistor R10). If the output voltage of the operational amplifier OP1 is relatively large, when a voltage value that is converted from the current value of the current I2 and the resistance value of the resistor R10 reaches the gate voltage of the transistor N4 (=the constant voltage Vreg), the transistor N4 is driven, and hence the node voltage V7 is kept (clamped) at the gate voltage of the transistor N4 (=the constant voltage Vreg).

Therefore, even if the current I1 output from the first voltage-current conversion circuit 507 has a relatively large current value, it is possible to suppress an excessive voltage from being applied to the noninverting input terminal (+) of the second overvoltage detection circuit C3. In this way, it is possible to suppress the second low voltage detection circuit C4 from being damaged.

If the second current-voltage conversion circuit 512 has a configuration including a transistor, the transistor is disposed between the current mirror circuit 513 and the first terminal of the resistor R14 (not shown). This transistor keeps the node voltage V11 to be the constant voltage Vreg or lower, in the same manner as the above transistor N4. For this reason, even if the current I3 output from the second voltage-current conversion circuit 511 has a relatively large current value, it is possible to suppress an excessive voltage from being applied to the noninverting input terminal (+) of the second low voltage detection circuit C4. In this way, it is possible to suppress the second low voltage detection circuit C4 from being damaged.

### Implementation Example of Signal Transmission Device 200

FIG. 16 is a block diagram illustrating an implementation example of the signal transmission device 200 of the present disclosure. The electronic device 400, in which the signal transmission device 200 of the present disclosure is mounted, can be appropriately used for a vehicle 450 such as an engine vehicle or an electric vehicle. The electronic device 400 can be appropriately used as a motor driving device that performs drive control of the motor M mounted in the vehicle 450.

As illustrated in FIG. 16, the motor M is a three-phase motor that is driven to rotate by three phase drive voltages U, V, and W input from half-bridge output stages of three phases (U-phase, V-phase, and W-phase).

The electronic device 400 includes three insulated gate drivers 1H(u, v, and w), three insulated gate drivers 1L(u, v, and w), three high side switching elements SWH(u, v, and w), three low side switching elements SWL(u, v, and w), the ECU 2, and a smoothing capacitor 600.

Each of the insulated gate drivers 1H(u, v, and w) insulates between the ECU 2 and the high side switching element SWH(u, v, or w), and generates an upper side gate drive signal (corresponding to the above-mentioned output signal OUT) in accordance with an upper side gate control signal (corresponding to the above-mentioned input signal IN) input from the ECU 2, so as to drive the high side switching element SWH(u, v, or w).

Each of the insulated gate drivers 1L(u, v, and w) insulates between the ECU 2 and the low side switching element SWL(u, v, or w), and generates a lower side gate drive signal in accordance with a lower side gate control signal input from the ECU 2, so as to drive the low side switching element SWL(u, v, or w).

The high side switching elements SWH(u, v, and w) are gate driven by the insulated gate drivers 1H(u, v, and w), respectively. In addition, each of the high side switching elements SWH(u, v, and w) is connected between a power system power supply terminal (=an application terminal of a first motor drive voltage VD1) and each phase input terminal of the motor M.

The low side switching element SWL(u, v, and w) are gate driven by the insulated gate drivers 1L(u, v, and w), respectively. In addition, each of the low side switching elements SWL(u, v, and w) is connected between each phase input terminal of the motor M and a power system ground terminal (=an application terminal of a second motor drive voltage VD2).

Note that in this diagram, an IGBT is used for each of the high side switching elements SWH(u, v, and w) and the low side switching elements SWL(u, v, and w), but it is possible to use an SiC-MOSFET or an Si-MOSFET instead of an IGBT, as described above.

The ECU 2 drives the high side switching elements SWH(u, v, and w) and the low side switching elements SWL(u, v, and w) via the insulated gate drivers 1H(u, v, and w) and 1L(u, v, and w), respectively, so as to control rotation drive of the motor M. In addition, the ECU 2 also has a function of monitoring a terminal FLT1 and terminal FLT2 of each of the insulated gate drivers 1H(u, v, and w) and 1L(u, v, and w), so as to perform various safety controls.

The smoothing capacitor 600 is provided, which smooths a voltage between the first motor drive voltage VD1 and an application terminal of the second motor drive voltage VD2. The smoothing capacitor 600 stabilizes a DC voltage (=the voltage between the first motor drive voltage VD1 and the application terminal of the second motor drive voltage VD2), which varies in accordance with a variation of power consumption of the motor M.

Here, as each of the insulated gate drivers 1H(u, v, and w) and 1L(u, v, and w), the above-mentioned signal transmission device 200 can be used appropriately. For instance, the insulated gate driver 1H and the insulated gate driver 1L of one phase among three phases (e.g., U-phase with reference to this diagram) can be the above-mentioned signal transmission device 200.

Note that when the above-mentioned signal transmission device 200 is used as the insulated gate driver 1H(u, v, or w), the switch SW in FIG. 10 is the high side switch SWH(u, v, or w) in FIG. 16. In this case, the node n1 illustrated in FIG. 10 can be said to be an application terminal of the first motor drive voltage VD1 in FIG. 16. In addition, the node n2 illustrated in FIG. 10 can be said to be a connection terminal to the motor M in FIG. 16.

In addition, when the above-mentioned signal transmission device 200 is used as the insulated gate driver 1L(u, v, or w), the switch SW in FIG. 10 is the low side switch SWL(u, v, or w) in FIG. 16. In this case, the node n1 illustrated in FIG. 10 can be said to be a connection terminal to the motor M in FIG. 16. In addition, the node n2 illustrated in FIG. 10 can be said to be an application terminal of the second motor drive voltage VD2 in FIG. 16.

### Variations

Other than that, the present invention is not limited to the embodiments described above, but can be variously modified within the scope of the present invention without deviating from the spirit thereof. For instance, although the first voltage-current conversion circuit 507 and the second voltage-current conversion circuit 511 are denoted by different numerals, and are described as different components, for convenience' sake of description in the embodiments described above, it may be possible to adopt a configuration in which the circuits are commonized as the same configuration. In the same manner, although the first current-voltage conversion circuit 508 and the second current-voltage conversion circuit 512 are denoted by different numerals, and are described as different components, it may be possible to adopt a configuration in which the circuits are commonized as the same configuration.

In the same manner, it may also be possible to adopt a configuration, in which the configuration for generating the divided voltage V2 with the resistor R3 and the resistor R4, and the configuration for generating the divided voltage V4 with the resistor R5 and the resistor R6, are commonized as the same configuration.

Although an insulated gate bipolar transistor (IGBT) is used as each of the switching element SW, the high side switching elements SWH(u, v, and w), and the low side switching elements SWL(u, v, and w) in this implementation example, the configuration of the half-bridge output stage is not limited to this, but it may be possible to adopt a MOS field-effect transistor using SiC semiconductor or a MOS field-effect transistor using Si semiconductor.

### Additional Notes

An abnormal voltage protection circuit (502) disclosed in the specification is configured to include a voltage-current conversion circuit (507, 511) configured to convert a monitor target voltage (VEE2) being negative with respect to a reference voltage into a current signal (I1, I3), a current-voltage conversion circuit configured to convert the current signal (I1, I3) into a voltage signal (V7, V11) being positive with respect to the reference voltage, and an abnormal voltage detection circuit (C3, C4) configured to be capable of detecting whether or not the monitor target voltage (VEE2) is an upper limit voltage (V8) or higher, or a lower limit voltage (V12) or lower, by comparing the voltage signal (V7, V11) with a threshold value voltage (V8, V12) (first configuration).

Note that the abnormal voltage protection circuit (502) according to the first configuration preferably has a configuration (second configuration), in which the reference voltage is a ground voltage (GND2).

In addition, the abnormal voltage protection circuit (502) according to the first or the second configuration preferably has a configuration (third configuration), in which the abnormal voltage detection circuit (C3, C4) has a first terminal to which the voltage signal (V7, V11) is input, a second terminal to which the threshold value voltage (V8, V12) is input, a third terminal to which a positive power supply voltage (Vreg) being positive with respect to a reference voltage is input, and a fourth terminal to which the reference voltage is input, so as to operate by inputting the positive power supply voltage (Vreg) and the reference voltage, and to output a detection signal (S6, S7) corresponding to a potential difference between the voltage signal (V7, V11) and the threshold value voltage (V8, V12), and a clamp circuit (N4) is provided so as to keep a voltage value of the voltage signal (V7, V11) input to the first terminal to be the positive power supply voltage (Vreg) or lower.

A signal transmission device (200) disclosed in the specification is configured to include a first chip (410), a second chip (420), and a third chip (430) configured to perform signal transmission while insulating between the first chip (410) and the second chip (420), in which the second chip (420) is configured to include integrated circuit elements including the abnormal voltage protection circuit (502) according to any one of the first to third configurations, and the third chip (430) is configured to transmit a detection result of the abnormal voltage detection circuit (C3, C4) from the second chip (420) to the first chip (410) (fourth configuration).

In addition, the signal transmission device (200) according to the fourth configuration preferably has a configuration (fifth configuration), in which the first chip (410) has an input terminal (IN) for receiving an input signal as an external input, and an output terminal (T1 to T4) for externally outputting an output signal (S4 to S7) corresponding to the detection result.

An electronic device disclosed in the specification is configured to include a plurality of switching elements each being a power transistor, a plurality of gate driver ICs configured to drive the gates of the plurality of switching elements, respectively, and a control circuit configured to control the plurality of gate driver ICs, in which at least one of the plurality of gate driver ICs is the signal transmission device (200) according to the fifth configuration, and the first chip (410) inputs the output signal (S4 to S7) to the control circuit via the output terminal (T1 to T4), while receiving the input signal from the control circuit via the input terminal (IN) (sixth configuration).

A vehicle (450) disclosed in the specification is configured to include the electronic device according to the sixth configuration (seventh configuration).

With the abnormal voltage protection circuit (502) according to the first configuration, it is possible to detect a state where the monitor target voltage (VEE2) being negative with respect to a reference voltage is the predetermined upper limit voltage (V8) or higher, or the predetermined lower limit voltage (V12) or lower.

With the abnormal voltage protection circuit (502) according to the second configuration, it is possible to implement a protection function for the monitor target voltage (VEE2) with respect to the ground voltage (GND2).

With the abnormal voltage protection circuit (502) according to the third configuration, it is possible to suppress the voltage signal (V7, V11) input to the first terminal from being excessive. In this way, it is possible to suppress the abnormal voltage detection circuit (C3, C4) from being broken.

With the signal transmission device (200) according to the fourth configuration, when the monitor target voltage (VEE2) being negative with respect to a reference voltage is in an abnormal voltage state, it is possible to protect circuits in the third chip (430).

With the signal transmission device (200) according to the fifth configuration, it is possible to externally output the detection result, and it is possible to input the input signal to realize the control corresponding to the detection result.

With the electronic device according to the sixth configuration, it is possible to protect the signal transmission device (200), when the monitor target voltage (VEE2) being negative with respect to a reference voltage is in an abnormal voltage state.

With the vehicle (450) according to the seventh configuration, it is possible to protect the signal transmission device (200), when the monitor target voltage (VEE2) being negative with respect to a reference voltage is in an abnormal voltage state.

### LIST OF REFERENCE SIGNS

5 semiconductor device
11, 11A-11F low-potential terminal
12, 12A-12F high-potential terminal
21, 21A-21D transformer
22 low-potential coil (primary coil)
23 high-potential coil (secondary coil)
24 first inner end
25 first outer end
26 first spiral portion
27 second inner end
28 second outer end
29 second spiral portion
31 first low-potential wiring
32 second low-potential wiring
33 first high-potential wiring
34 second high-potential wiring
41 semiconductor chip
42 first principal surface
43 second principal surface
44A-44D chip side wall
45 first functional device
51 insulation layer
52 insulation principal surface
53A-53D insulation side wall
55 bottom insulation layer
56 top insulation layer
57 interlayer insulation layer
58 first insulation layer
59 second insulation layer
60 second functional device
61 sealing conductor
62 device region
63 outer region
64 sealing plug conductor
65 sealing via conductor
66 first inner region
67 second inner region
71 through wiring
72 low-potential connection wiring
73 lead wiring
74 first connection plug electrode
75 second connection plug electrode
76 pad plug electrode
77 substrate plug electrode
78 first electrode layer
79 second electrode layer
80 wiring plug electrode
81 high-potential connection wiring
82 pad plug electrode
85 dummy pattern
86 high-potential dummy pattern
87 first high-potential dummy pattern
88 second high-potential dummy pattern
89 first region
90 second region
91 third region
92 first connection part
93 first pattern
94 second pattern
95 third pattern
96 first outer circumferential line
97 second outer circumferential line
98 first middle line
99 first connection line
100 slit
130 separation structure
140 inorganic insulation layer
141 first inorganic insulation layer
142 second inorganic insulation layer
143 low-potential pad opening
144 high-potential pad opening
145 organic insulation layer
146 first part
147 second part
148 low-potential terminal opening
149 high-potential terminal opening
200 signal transmission device
200p primary circuit system
200s secondary circuit system
210 controller chip (first chip)
211 pulse transmission circuit (pulse generator)
212, 213 buffer
220 driver chip (second chip)
221, 222 buffer
223 pulse reception circuit (RS flip-flop)
224 driver
230 transformer chip (third chip)
230a first wiring layer (lower layer)
230b second wiring layer (upper layer)
231, 232 transformer
231p, 232p primary coil
231s, 232s secondary coil
300 transformer chip
301 first transformer
302 second transformer
303 third transformer
304 fourth transformer
305 first guard ring
306 second guard ring
a1-a8 pad (corresponding to first current feed pad)
b1-b8 pad (corresponding to first voltage measurement pad)
c1-c4 pad (corresponding to second current feed pad)
d1-d4 pad (corresponding to second voltage measurement pad)
e1, e2 pad
L1s, L2s, L3s, L4s secondary coil
T21, T22, T23, T24, T25, T26 external terminal
X first direction
X21, X22, X23 internal terminal
Y second direction
Y21, Y22, Y23 wiring
Z normal direction
Z21, Z22, Z23via
400 electronic device
410 first semiconductor chip
411 first transmission circuit
412 second transmission circuit
415 logic circuit
416 third reception circuit
417 fourth reception circuit
418 fifth reception circuit
419 sixth reception circuit
420 second semiconductor chip
421 first reception circuit
422 second reception circuit
424 driver circuit
425 logic circuit
426 third transmission circuit
427 fourth transmission circuit
428 fifth transmission circuit
429 sixth transmission circuit
430 third semiconductor chip
431 first transformer
432 second transformer
433 third transformer
434 fourth transformer
435 fifth transformer
436 sixth transformer
450 vehicle
501 output circuit
502 abnormal voltage protection circuit
503 first overvoltage protection circuit
504 first low voltage malfunction prevention circuit
505 second overvoltage protection circuit
506 second low voltage malfunction prevention circuit
507 first voltage-current conversion circuit
508 first current-voltage conversion circuit
510 current mirror circuit
511 second voltage-current conversion circuit
512 second current-voltage conversion circuit
513 current mirror circuit
600 smoothing capacitor
C1 first overvoltage detection circuit
C2 first low voltage detection circuit
C3 second overvoltage detection circuit
C4 second low voltage detection circuit
D1, D2diode
E1 voltage source
E2 voltage source
GND2 ground voltage
Ga-Gc drive signal
I1-I4 current
IN input signal
OP1 operational amplifier
OP2 operational amplifier
OUT output signal
N1-N4 transistor
P1-P5 transistor
R1-R14 resistor
S1 first internal signal
S2 second internal signal
S3 driver control signal
S4-S7 detection signal
SW switching element
SWH high side switching element
SWL low side switching element
T1 first detection signal output terminal
T2 second detection signal output terminal
T3 third detection signal output terminal
T4 fourth detection signal output terminal
T21-T26 external terminal
U drive voltage
V1 first upper limit voltage
V2 divided voltage
V3 first lower limit voltage
V4 divided voltage
V5 divided voltage
V6 node voltage
V7 node voltage
V8 second upper limit voltage
V9 divided voltage
V10 node voltage
V11 node voltage
V12 second lower limit voltage
VCC2 positive power supply voltage
VEE2 negative power supply voltage
VD1 first motor drive voltage
VD2 second motor drive voltage

1. An abnormal voltage protection circuit comprising:
a voltage-current conversion circuit configured to convert a monitor target voltage being negative with respect to a reference voltage into a current signal;
a current-voltage conversion circuit configured to convert the current signal to a voltage signal being positive with respect to a reference voltage; and
an abnormal voltage detection circuit configured to be capable of detecting whether or not the monitor target voltage is an upper limit voltage or higher, or a lower limit voltage or lower, by comparing the voltage signal with a threshold value voltage.

2. The abnormal voltage protection circuit according to claim 1, wherein the reference voltage is a ground voltage.

3. The abnormal voltage protection circuit according to claim 1, wherein
the abnormal voltage detection circuit has a first terminal to which the voltage signal is input, a second terminal to which the threshold value voltage is input, a third terminal to which a positive power supply voltage being positive with respect to a reference voltage is input, and a fourth terminal to which the reference voltage is input, so as to operate by inputting the positive power supply voltage and the reference voltage, and to output a detection signal corresponding to a potential difference between the voltage signal and the threshold value voltage, and
a clamp circuit is provided so as to keep a voltage value of the voltage signal input to the first terminal to be the positive power supply voltage or lower.

4. A signal transmission device comprising a first chip, a second chip, and a third chip configured to perform signal transmission while insulating between the first chip and the second chip, wherein
the second chip is configured to include integrated circuit elements including the abnormal voltage protection circuit according to claim 1, and
the third chip is configured to transmit a detection result of the abnormal voltage detection circuit from the second chip to the first chip.

5. The signal transmission device according to claim 4, wherein the first chip has an input terminal for receiving an input signal as an external input, and an output terminal for externally outputting an output signal corresponding to the detection result.

6. An electronic device comprising:
a plurality of switching elements each being a power transistor;
a plurality of gate driver ICs configured to drive the gates of the plurality of switching elements, respectively; and
a control circuit configured to control the plurality of gate driver ICs, wherein
at least one of the plurality of gate driver ICs is the signal transmission device according to claim 5, and
the first chip inputs the output signal to the control circuit via the output terminal, while receiving the input signal from the control circuit via the input terminal.

7. A vehicle comprising an electronic device according to claim 6.
